(19) United States
(12) Patent Application Publication
(10) Pub. No.: US 2017/0371243 A1
(43) Pub. Date: Dec. 28, 2017

(54) MICRON PATTERNED SILICONE HARD-COATED POLYMER (SHC-P) SURFACES

(71) Applicant: SABIC Global Technologies B.V., Bergen op Zoom (NL)

(72) Inventors: Abdiaziz A. Farah, Thuwal (SA); Jesus Alfonso Caraveo Frescas, Thuwal (SA); Albraa A. Jaber, Thuwal (SA)

(21) Appl. No.: 15/525,316

(22) PCT Filed: Nov. 17, 2016
(86) PCT No.: PCT/IB2016/056940

§ 371 Date: May 9, 2017

Related U.S. Application Data
(60) Provisional application No. 62/261,660, filed on Dec. 1, 2015.

(51) Int. Cl. G03F 7/075; G03F 7/38; G03F 7/42; G03F 7/30; G03F 7/20; G03F 7/16

(52) U.S. Cl. CPC G03F 7/0752; G03F 7/38; G03F 7/427; G03F 7/20; G03F 7/162; G03F 7/30

(57) ABSTRACT

In this invention use of silicone hard-coated polycarbonate (SHC-PC) as direct photo definable, thermally, chemically and optically stable polymer that can be patterned using conventional microfabrication and drying etching process is reported. As a result of the increased resistance to thermal and chemical deformations and flow of the silicone hard-coated polycarbonate (SHC-PC), it has been shown for the first time that the illustrated process herein to be compatible with a variety of conventional thin film deposition, micro and nano fabrication approaches such as metal evaporation, photoresist deposition/developing and electroplating that are typically incompatible to polycarbonate. As such high optical clarity surfaces with ultra-hydrophobic-hydrophilic properties with well-defined micro and nano patterned surface features of high surface roughness were fabricated with high fidelity.

### CROSS-REFERENCE TO RELATED APPLICATIONS

This application claims the benefit of priority of U.S. Provisional Patent Application No. 62/261,660, filed Dec. 1, 2015, which is hereby incorporated by reference in its entirety.

### BACKGROUND

Certain aspects of current research in material science is focused on fabrication of thermoplastic surfaces with micron and nano-sized features with high fidelity in combination with superior water repellency. Notably, the lotus leaf mimicking surfaces that exhibit an inherent self-cleaning mechanism resulting from micron-sized waxy bumps protruding from its surface so that water is naturally repelled removing any foreign dirt. This remarkable cleansing mechanism, coined the “lotus effect,” has been artificially mimicked to produce materials with pronounced hydrophobicity. Noteworthy examples of fabricating nano-textured materials include surface patterning, layer by layer and molecular self-assembly, etching and deposition methods, and electrochemical approaches. However, these examples require aggressive chemical surface treatments, high temperature post-surface modifications, elaborate patterning and the need of hardly accessible deposition equipment. For such reasons, there exist a demand to construct long lasting micron patterned polymeric surfaces that are easy to prepare on a large scale.

### SUMMARY

Patterned polycarbonate surfaces have been produced by a number of different approaches including hot embossing and injection molding techniques, solvent induced crystallization, laser micromachining, imprinting at room temperature, and plasma nano-structuring approaches. However, it is difficult to achieve solution processable patterned polycarbonate surfaces through conventional nanofabrication approach that is immune to swelling, melting, or becoming opaque during a large scale production. Embodiments of the present disclosure describe methods of producing micron patterned surfaces that provide solutions to these short comings, as well as materials and devices incorporating the same. The processes are unique and obtain well-defined patterns with various geometries (e.g., rectangular, squares, circles, pyramids etc.) and shape types. The processes are also able to produce nanostructures in sizes and shapes that can be produced on large scale with fidelity on SHC-PC while mediating chemical, UV, and abrasion limitations that are typical for polycarbonate.

Aspects of the invention use of silicone hard-coated polycarbonate (SHC-PC) as direct photo definable, thermally, chemically and optically stable polymer that can be patterned using conventional microfabrication and drying etching process. As a result of the increased resistance to thermal and chemical deformations and flow of the silicone hard-coated polycarbonate (SHC-PC), it has been shown for the first time that the illustrated process herein to be compatible with a variety of conventional thin film deposition, micro and nano fabrication approaches such as metal evaporation, photoresist deposition/developing and electroplating that are typically incompatible to polycarbonate. As such high optical clarity surfaces with ultra-hydrophobic-hydrophilic properties with well-defined micro and nano patterned surface features of high surface roughness were fabricated with high fidelity.

Certain embodiments of the disclosure describe the preparation of thermal, chemical, and UV resistant micron patterned silicone hard-coated polycarbonate (SHC-PC) surfaces that are transparent to visible light using a combination of wet nanofabrication and dry plasma etching approaches. Processes described herein can be used to obtain well-defined patterns with different geometries (rectangular, squares, circles and pyramid) shape types on SHC-PC surfaces. The nanostructures can be produced on large scale with fidelity on SHC-PC, surpassing the chemical, UV, and abrasion constraints characteristic for polycarbonate.

Polycarbonates (PC) are a group of thermoplastic polymers containing carbonate groups in their chemical structures. Polycarbonates used in engineering are strong, tough materials, and some grades are optically transparent. They are easily worked, molded, and thermoformed. Polycarbonate is a durable material with high impact-resistance, but have a low scratch-resistance. In certain situations a hard coating is applied to polycarbonate to increase its weatherability.

In certain instances a polymer such as polycarbonate is coated with a silicone hard-coat. Silicones are polymers that include any inert, synthetic compound made up of repeating units of siloxane, which is a functional group of two silicon atoms and one oxygen atom frequently combined with carbon and/or hydrogen.

Certain embodiments are directed to a micron patterned silicone hard-coated polymer comprising a micro patterned surface having (a) three-dimensional surface features and (b) a water contact angle (WCA) of between 15° and 125°. The three dimensional surface features can have a rectangular, square, polygonal, circular, or elliptical base. In certain aspects the surface features are semi-spherical, cubes, polygonal columns, cylinders, cones, triangular prisms, or pyramids. In a particular aspect a polygonal column is a rectangular column. The surface features can be at least, at most, or about 1, 2, 3, 4, 5 to 6, 7, 8, 9, 10 μm in height. In certain aspect the surface features are about 1 to 10 μm in height. The surface features can have an aspect ratio of about 0.5 to 3 μm, including all values and ranges there between. In certain aspects the surface features are spaced at about 5 to 15 μm, including all values and ranges there between, center to center from each other. In certain aspects the surface has a roughness from 5 nm to 100 nm, including all values and ranges there between.

The micron patterned silicone hard-coated polymer can further comprise a hydrophobic coating forming a coated hydrophobic silicone hard-coated polymer. In certain aspects the hydrophobic coating has a thickness of 5 nm to 1 μm, including all values and ranges there between. The hydrophobic coating can be a fluorinated polymeric film. In certain aspects the fluorinated polymeric film is a C₄F₈, CF₄, polytetrafluoroethylene (PTFE), polychlorotrifluoroethylene (PCTFE), polyvinylidenefluoride (PVDF), polyvinylfluoride (PVF), ethylene/chlorotrifluoroethylene copolymer (ECTFE), ethylene/trifluoroethylene copolymer (ETFE), fluorinated ethylene/propylene copolymer (FEP), trifluoroethylene/perfluoropropylvinylether (PFA), poly(TFE-co-HFP-co-VDF) (THV), perfluoro-3-butenyl-vinly ether (PBVE), or tetrafluoroethylene/perfluoro-2,2-dimethyl-1,3-dioxole copolymer polymeric film. In a further aspect the coated hydrophobic hard-coated polymer has a surface composition of about 45 to 50% O1s, 9 to 11% C1s, 1 to 3% F1s, and 30 to 45% Si2p. In certain aspects the polymer of the micron patterned silicone hard-coated polymer is polycarbonate or similar material. The micron patterned silicone hard-coated polymers described herein can be mechanically flexible and have a bend radius of between 0.005 to 10 mm.

The micron patterned silicone hard-coated polymers described herein can be resistant to organic solvents, resistant to ultraviolet light up to 500 mJ/cm², thermally stable at temperatures between 20° C. and 200° C., or any combination thereof. In certain aspects the micron patterned silicone hard-coated polymers described herein are resistant to organic solvents, resistant to ultraviolet light up to 500 mJ/cm², and thermally stable at temperatures between 20° C. and 200° C.

The micron patterned silicone hard-coated polymers described herein can be opaque to ultraviolet light, blocking or absorbing ultraviolet light to some degree. In certain aspects the micron patterned silicone hard-coated polymer transmits less than 1, 5, 10, or 20% of incident ultraviolet light. In further aspects the micron patterned silicone hard-coated polymer transmits less than 10% of incident ultraviolet light. The micron patterned silicone hard-coated polymer can be transparent to visible light. In certain aspects the micron patterned silicone hard-coated polymers described herein transmits at least 70, 80, or 90% of incident visible light. In still a further aspect the micron patterned silicone hard-coated polymers described herein transmits at least 90% of incident visible light.

Certain embodiments are directed to a flexible film comprising a micron patterned hard-coated polymer as described herein. In certain aspects the micron patterned hard-coated polymer comprises a micropatterned surface having (a) three-dimensional surface features, and (b) a water contact angle (WCA) of between 15° and 125° that is mechanically flexible and has a bend radius of between 0.005 to 10 mm.

Further embodiments are directed to microfluidic or micromechanical devices incorporating the micron patterned silicone hard-coated polymers to form one or more layers, surfaces, channels, and/or wells within the device. Certain embodiments are directed to a microfluidic or micromechanical device comprising a silicone hard-coated polymer having three-dimensional surface features and a water contact angle (WCA) greater than 90°. The three dimensional surface features can have a rectangular, square, polygonal, circular, or elliptical base. In certain aspects the three dimensional surface features are semi-spherical, cubes, polygonal columns, cylinders, cones, triangular prisms, or pyramids. In a particular aspect the polygonal column is a rectangular column. The three dimensional surface features can be about 1 to 10 μm in height and have an aspect ratio of about 0.5 to 3 μm. In certain aspect the three dimensional surface features are spaced at about 5 to 15 μm center to center from each other. The surface of the silicone hard-coated polymer portion(s) of a device can have a roughness from 5 nm to 100 nm. In certain aspects the surface can have a hydrophobic coating. The hydrophobic coating can have a thickness of 5 nm to 1 μm. The coating can be a fluorinated polymeric film. In certain aspects the fluorinated polymeric film is a C₄F₈, CF₄, polytetrafluoroethylene (PTFE), polychlorotrifluoroethylene (PCTFE), polyvinylidenefluoride (PVDF), polyvinylfluoride (PVF), ethylene/chlorotrifluoroethylene copolymer (ECTFE), ethylene/trifluoroethylene copolymer (ETFE), fluorinated ethylene/propylene copolymer (FEP), trifluoroethylene/perfluoropropylvinylether (PFA), poly(TFE-co-HFP-co-VDF) (THV), perfluoro-3-butenyl-vinly ether (PBVE), or tetrafluoroethylene/perfluoro-2,2-dimethyl-1,3-dioxole copolymer polymeric film. In a further aspect hydrophobic coated hard-coated polymer has a surface composition of about 45 to 50% O1s, 9 to 11% C1s, 1 to 3% F1s, and 30 to 45% Si2p. The coated polymer can be polycarbonate or a similar material. The micron patterned silicon hard-coated polymer can be resistant to ultraviolet light up to 500 mJ/cm², thermally stable at temperatures between 20° C. and 200° C., and resistant to organic solvents. In certain aspect the micron patterned silicone hard-coated polymer portion of a device can absorb or block ultraviolet light. In certain aspects the micron patterned silicone hard-coated polymer portion of the device transmits less than 10% of incident ultraviolet light. The micron patterned silicone hard-coated polymer portions of the device can be transparent to visible light. In certain aspects the micron patterned silicone hard-coated polymer transmits at least 90% of incident visible light. In other aspects the silicone hard-coated polymer is resistant to organic solvents. In still a further aspect the silicone hard-coated polymer absorbs ultraviolet light. The silicone hard-coated polymer can transmit less than 10% of incident ultraviolet light. The silicone hard-coated polymer can be transparent to visible light. In certain aspects the silicone hard-coated polymer transmits at least 90% of incident visible light.

Other embodiments described herein are directed to methods for micropatterning a silicone hard-coated (SHC) substrate comprising the steps of: (a) applying a photoresist (PR) coating to a silicone hard-coated substrate surface to form a photoresist coated silicone hard-coated substrate; (b) exposing the photoresist coated silicone hard-coated substrate to ultraviolet light in the presence of a photomask; (c) developing the exposed photoresist coated silicone hard-coated substrate to form a patterned silicone hard-coated substrate; (d) exposing the patterned silicone hard-coated substrate to a first plasma etching to form a first plasma etched silicone hard-coated substrate; and (e) exposing the first plasma etched silicone hard-coated substrate to a second plasma etching comprising reactive ion-etching (ME) to form a micron patterned silicone hard-coated substrate. The method can further comprise applying a metal mask to portions of the silicone hard-coated substrate prior to applying the photoresist coating. In certain aspects applying the photoresist is by spin-coating the silicone hard-coated substrate with the photoresist. The photoresist layer can be between 1 and 10 μm thick. In certain aspects the photoresist layer is about 4 μm thick. In certain aspects the photoresist is a positive photoresist, such as but not limited to ECI 3027 photoresist. The first plasma etching can be an O₂/Ar plasma etching. In certain aspects the O₂/Ar plasma mixture has an oxygen percentage from 1 to 99%. In a further aspect the O₂/Ar plasma processing pressure ranges from 2 mTorr to 50 Torr. In certain aspects the O₂/Ar plasma processing is performed at a power of 100 W to 1000 W. The O₂/Ar plasma processing is performed at a temperature below the glass transition temperature of a polymer coated with the silicone hard coat. In certain aspects the O₂/Ar plasma processing is performed at a temperature below 140° C. In certain aspects the second deep reactive ion etching is performed using the Bosch process of deep reactive ion-etching. The second plasma etching can be performed using a C₄F₈ or CF₄ flux.

The methods can further comprise modifying the surface of the silicone hard-coat surface by coating the surface with a fluorinated polymeric film. In certain aspects the fluorinated polymeric film is 5 nm to 1 μm thick. In a further aspect the fluorinated polymeric film is a C₄F₈ or CF₄ film.

As used herein the term “transparent” as used herein encompasses average transmission of a straight through beam of 45% or more across a particular electromagnetic band. The term “near-infrared” (NIR) and “near-infrared band” as recited herein is defined as light having wavelengths in the range from the upper edge of the visible band (about 650 nm) to about 2-3 μm. The term “ultraviolet” (UV) and “ultraviolet band” as recited herein is defined as light having wavelengths from the lower edge of the visible band (about 450 nm) and less. The term “visible light” and “visible band” as recited herein is defined as light having wavelengths to which the human eye has a significant response, from about 435 nm to about 670 nm.

Surface roughness can be expressed as the average surface roughness as determined at several regions of the surface. A non-limiting example of a suitable method for determining the surface roughness of the surface or of a region thereof is ISO13565.

The term “thermoplastic polymer” is used herein to mean any polymer that softens at increased temperature. One example of a thermoplastic polymer is a polycarbonate polymer.

The terms “photografting” or “photoinitiated grafting” are used interchangeably herein to mean a process wherein ultra-violet light is used to initiate a polymerization reaction that originates from the surface of the substrate that is grafted upon.

Other embodiments of the invention are discussed throughout this application. Any embodiment discussed with respect to one aspect of the invention applies to other aspects of the invention as well and vice versa. Each embodiment described herein is understood to be embodiments of the invention that are applicable to all aspects of the invention. It is contemplated that any embodiment discussed herein can be implemented with respect to any method or composition of the invention, and vice versa. Furthermore, compositions and kits of the invention can be used to achieve methods of the invention.

The use of the word “a” or “an” when used in conjunction with the term “comprising” in the claims and/or the specification may mean “one,” but it is also consistent with the meaning of “one or more,” “at least one,” and “one or more than one.”

Throughout this application, the term “about” is used to indicate that a value includes the standard deviation of error for the device or method being employed to determine the value.

The use of the term “or” in the claims is used to mean “and/or” unless explicitly indicated to refer to alternatives only or the alternatives are mutually exclusive, although the disclosure supports a definition that refers to only alternatives and “and/or.”

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps.

Other objects, features and advantages of the present invention will become apparent from the following detailed description. It should be understood, however, that the detailed description and the specific examples, while indicating specific embodiments of the invention, are given by way of illustration only, since various changes and modifications within the spirit and scope of the invention will become apparent to those skilled in the art from this detailed description.

### DESCRIPTION OF THE DRAWINGS

The following drawings form part of the present specification and are included to further demonstrate certain aspects of the present invention. The invention may be better understood by reference to one or more of these drawings in combination with the detailed description of the specification embodiments presented herein.

FIG. 1. Wet nanofabrication process of polycarbonate (PC) (Lexan) and Silicone hard-coated polycarbonate (SHC-PC).

FIG. 2. Representative SEM images of micro-patterned (SHP-PC) (rectangular and circular patterns) shown at three different magnifications.

FIG. 3. Representative SEM images of micro-patterned (SHC-PC) (rectangular and circular pattern) exposed to different oxygen plasma time.

FIGS. 4A-C. Representative surface height maps of micro-patterned polycarbonate (PC) (Lexan) (rectangular patterns). (A) Flat surface map, (B) 3-Dimensional surface plot, (C) Surface profile image.

FIGS. 5A-D. (A). XPS survey spectra of micro-patterned silicone hard-coated polycarbonate (SHC-PC) (rectangular patterns) surface. (B) High-resolution C is spectra, (C) High-resolution O 1s spectra, (D) High-resolution F is spectra.

### DESCRIPTION

Superhydrophobic surfaces are widely present in nature. Examples include the lotus leaf that can self-clean and the water strider insect that can rest on water using water-repellent legs. Another example is the desert beetle that can collect water by hydrophilic and hydrophobic surfaces in desert wind. These natural superhydrophobic surfaces have led scientists to try to produce surfaces having different wetting ability for application in a large range of manufacturing, industrial, agricultural, and household settings. A superhydrophobic surface is generally characterized by having a high advancing contact angle, above 150 degrees, low hysteresis angle, and easy roll-off. It is known that water may contact superhydrophobic surfaces in two different states: the Wenzel state and the Cassie-Baxter state. In the Wenzel state, water droplets become pinned to the surface even when the surface is tilted. In contrast, in the Cassie-Baxter state, water droplets sit partially on surface air pockets and roll off easily on a tilted surface.

Described herein are processes for producing hydrophobic surfaces that are have a micron patterned surface. In certain aspects the micron patterned surfaces are silicone hard-coated polymer surfaces. The micron patterned surfaces can comprise micron hierarchical structures that include, but are not limited to rectangular, circular, square and pyramid type shapes that are formed using a combination of high fidelity nanofabrication procedures.

Recently, thermoplastic engineering materials have been shown to be alternatives to glass, quartz, and silicon in the fabrication of miniaturized devices. Among these materials, polycarbonate PC (Lexan) is known to possess high impact resistance, high glass transition temperature, low moisture absorption, and excellent optical transparency that makes it a candidate for a low cost and scalable material with an ultra and superhydrophobic surface. However, poor chemical resistance to most common organic solvents and UV degradation are major constraints of polycarbonate. To mitigate these problems known methods of treating polycarbonate include the application of one or more layers of abrasion resistant material and UV absorbing material to the polycarbonate substrate. Use of silicone hard-coated polycarbonate as described herein, is an example in which a silicone layer is applied to the polycarbonate substrate by dipping, spraying, or coating. The silicone layer comprises a dispersion of colloidal silica in a lower aliphatic alcohol-water solution of the partial condensate of a silanol. The silicone layer provides abrasion resistance to the polycarbonate and may also comprise of constituent which absorbs UV radiation. It also renders polycarbonate resistant to common organic solvents and it is compatible to the processes that demand the use of high temperature conditions.

Polycarbonate has found extensive acceptance as a material with outstanding impact strength, superior dimensional stability, glass-like transparency, excellent thermal resistance, and low-temperature toughness. Polycarbonate is widely used in a broad range of industries, including automotive and transportation, building and construction, electrical and electronics, telecommunication, packaging, medical, optical/opthalmic, and optical media. When polycarbonate is employed as a glass substitute, however, polycarbonate must be resistant to environmental influences (i.e., have weatherability or weathering stability).

Polycarbonates in the context of the present disclosure may be aliphatic or aromatic carbonate polymers. In general, the polycarbonates of the disclosure may be homopolycarbonates or copolycarbonates, meaning they may be synthesized using one or more type of dihydroxy-substituted aromatic hydrocarbon, and may also be linear or branched. Polycarbonates which contain both acid radicals of carbonic acid and acid radicals of aromatic dicarboxylic acids incorporated into the molecular chain, sometimes called aromatic polyester-carbonates, are also included under the generic term of polycarbonates. Polycarbonates include transparent polymer blends of polycarbonates with various other materials, such as polyesters and impact modifiers. Non-limiting examples of polycarbonates useful for the articles of the disclosure are MAKROLON®, manufactured by Bayer MaterialScience, and LEXAN®, produced by General Electric Company.

In certain aspects the patterned surfaces have a plurality of surface features (e.g., rectangular, circular, square and pyramid) shape types. The primary features include height dimension range from about 1 micron to 10 micron, aspect ratio from about 0.5 micron to 3 micron, and spacing of 5 to 15 micron width distance. The patterned materials provide for: (a) flexible ultra-hydrophobic and or superhydrophilic coating)(130°<WCA<15° on patterned SHC-polymer surfaces; (b) abrasion resistant and highly transparent nanopatterned SHC-polymer surfaces; (c) exceptional chemical, UV, and thermal resistance nanopatterned SHC-polymer; (d) good conformal nanopatterned SHC-polymer surfaces; and/or (e) nano-patterning SHC-polymer processes that is beneficial to micro-fluidic and microelectromechanical system (MEMS) miniaturized devices for sensor and diagnostic applications.

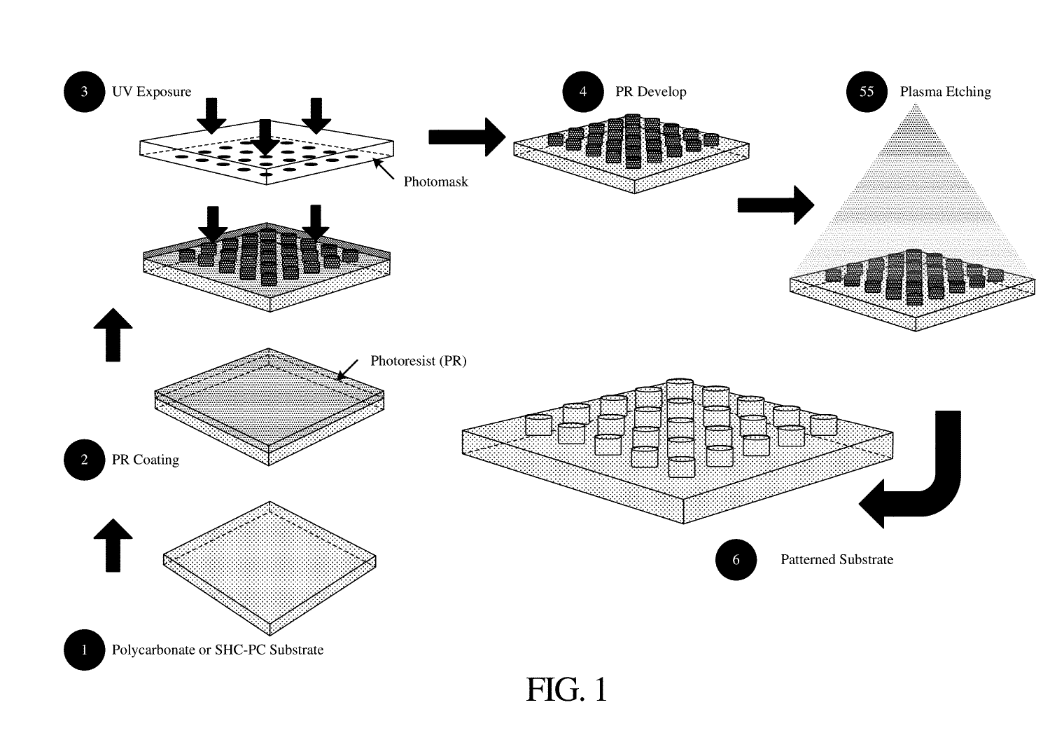

A wet nanofabrication process can be used to obtain micrometric features (typical parameters include, but are not limited to width=5 μm, height=10 μm and pitch=10 μm) on silicone hard-coated (SHC) polymer (e.g., polycarbonate (SHC-PC) or the like) sheets (FIG. 1). In one example, silicone hard-coated polycarbonate (SHC-PC) sheets of 1.5×1.5 cm² to 3×3 cm² are cleaned with isopropanol in an ultrasonic bath for 5 minutes, followed by DI water cleaning and blown dry with high purity nitrogen. In some processes a thin film of gold is sputter coated using an Angstrom system. A gold/aluminum sputtered film can serve as physical mask to create the desired nanostructures by final plasma etch.

A photolithography process is then used to replicate the pattern array which defines the position of rectangular, circular, square and pyramidal shape types. A 4 μm thick photoresist (PR) (e.g., EC3027) is spin-coated on the 4″ circular sample, followed by a soft baking process at 100° C. for 60 seconds. After spin-coating, a pre-baking step can be used to evaporate the solvent in order to achieve better adhesion between the metal layer and photoresist. The next step is the exposure of broadband UV light (e.g., in an EVG 6200 contact aligner) with an appropriate exposure dose (e.g., 200 mJ/cm⁻²) to crosslink the photoresist. The optical mask can be made of quartz with Cr features patterned by EBL system. A 60 s blank UV exposure (i.e., without the optical mask) is used to make the previously unexposed areas soluble. Then a developer (e.g., AZ 726 MIF) is used to create the array pattern for 60 s. The sample is rinsed copiously with deionized water and dried with nitrogen flux gently.

The final step consists of a two-step plasma etch processes. The first etch can be a hybrid etch process based on a gas mixture of O₂/Ar. The introduction of Argon (Ar) in the etchant gas mixture and reduction of oxygen avoids problems of extreme tapering due to slower etch rate. By optimizing the plasma processing parameters (i.e., pressure, electrical power, etch-period and gas ratios) micron patterned surfaces with an excellent aspect ratio and more well-defined vertical side walls are obtained. Specifically the use of a constant gas flow rate of 40 sccm of Ar at 1 Torr with RF power of 950 W and substrate temperature ˜40° C. achieving an etching rate ˜3.85 nms¹ can be used.

The second etch process can be a Reactive Ion-Etching (ME) (e.g., a Deep Reactive Ion Etch (DRIE)) having, for example, parameters of RF 13.56 MHz, Oxygen flux 50 sccm, C₄F₈ flux rate of 50 sccm, and 10 min and 20 min deposition time, respectively. After the PR removal and the metal mask in some cases, amorphous C₄F₈ polymeric layer 5-10 nm) are coated over the whole micron patterned surfaces.

Thermoplastic Materials for Substrates—

The methods described herein can be used for surface modification of a wide range of thermoplastic polymers. One representative example of such a thermoplastic is polycarbonate. Optical properties such as light transparency at the desired wavelength range (e.g., visible light) and resistance to a number of physical and chemical agents are beneficial characteristics of substrate materials for forming micron patterned silicone hard-coated polymers described herein. The chemical properties and solubility of the substrate or polymer can be taken into consideration. For instance, substrates that dissolve only in solvents for which they will not typically be in contact with when in use make a more desirable substrate for micron patterned silicone hard-coating.

In certain embodiments the polymer is a polycarbonate polymer. Polycarbonate is a transparent polymer comprising monomers containing hydrophobic phenyl and/or methyl groups and a hydrophilic carbonate group. Scanning electron microscope images of untreated polycarbonate show a smooth surface that exhibits medium hydrophobicity to a static water droplet on its surface. The surface of the polycarbonate can be treated and/or coated to provide additional beneficial properties.

Fabrication.

Removal is any process that removes material from a substrate or surface; examples include etch processes (either wet or dry) and chemical-mechanical planarization (CMP). Deposition is any process that grows, coats, or otherwise transfers a material onto a substrate or surface. Available technologies include physical vapor deposition (PVD), chemical vapor deposition (CVD), electrochemical deposition (ECD), molecular beam epitaxy (MBE) and more recently, atomic layer deposition (ALD) among others.

Patterning is the shaping or altering of a substrate or deposited materials, and is generally referred to as lithography. For example, in conventional lithography, the substrate is coated with a chemical called a photoresist; then, a machine called a stepper focuses, aligns, and moves a mask, exposing select portions of the substrate below to short wavelength light; the exposed regions are washed away by a developer solution. After etching or other processing, the remaining photoresist is removed by plasma ashing.

Photolithography, also termed optical lithography or UV lithography, is a process used in microfabrication to pattern parts of a thin film or the bulk of a substrate. It uses light to transfer a geometric pattern from a photomask to a light-sensitive chemical “photoresist”, or simply “resist,” on the substrate. A series of chemical treatments then either engraves the exposure pattern into, or enables deposition of a new material in the desired pattern upon, the material underneath the photo resist.

Photolithography shares some fundamental principles with photography in that the pattern in the etching resist is created by exposing it to light, either directly (without using a mask) or with a projected image using an optical mask. This procedure is comparable to a high precision version of the method used to make printed circuit boards. Subsequent stages in the process have more in common with etching than with lithographic printing. It is used because it can create extremely small patterns (down to a few tens of nanometers in size), it affords exact control over the shape and size of the objects it creates, and because it can create patterns over an entire surface cost-effectively. Its main disadvantages are that it requires a flat substrate to start with, it is not very effective at creating shapes that are not flat, and it can require extremely clean operating conditions. The methods described herein provide for effectively combining photolithography with etching to form micron or nano size three dimensional shapes on a silicon hard-coat.

Cleaning and Preparation.

If organic or inorganic contaminations are present on the substrate surface, they are usually removed by wet chemical treatment. Once cleaned, the wafer can be initially heated to a temperature sufficient to drive off any moisture that may be present on the wafer surface, for example in some instances heating to 150° C. for ten minutes is sufficient. A liquid or gaseous “adhesion promoter”, such as Bis(trimethylsilyl)amine (“hexamethyldisilazane”, HMDS), can be applied to promote adhesion of the photoresist to the substrate. The surface layer of the substrate reacts with the adhesion promoter to form a water repellent layer. This water repellent layer prevents the aqueous developer from penetrating between the photoresist layer and the substrate, thus preventing lifting of small photoresist structures in the (developing) pattern.

Photoresist Application.

The substrate can be covered with photoresist by spin coating or other coating process. In spin coating a viscous, liquid solution of photoresist is dispensed onto the substrate, and the substrate is spun rapidly to produce a uniformly thick layer. The spin coating typically runs at 1200 to 4800 rpm for 30 to 60 seconds, and produces a layer between 0.5 and 2.5 micrometers thick. The spin coating process results in a uniform thin layer, usually with uniformity of within 5 to 10 nanometers. The photo resist-coated substrate can then be prebaked to drive off excess photoresist solvent.

Exposure and Developing.

After prebaking, the photoresist can be exposed to a pattern of intense light. The exposure to light causes a chemical change that allows some of the photoresist to be removed by a developer solution. Positive photoresist, the most common type, becomes soluble in the developer when exposed; with negative photoresist, unexposed regions are soluble in the developer. A post-exposure bake (PEB) can be performed before developing. The developer can be delivered on a spinner, much like photoresist. The resulting substrate can then be “hard-baked” typically at 120 to 180° C. for 20 to 30 minutes. The hard bake solidifies the remaining photoresist, to make a more durable protecting layer in additional processing steps.

Etching.

In etching, a liquid (“wet”) or plasma (“dry”) chemical agent removes the uppermost layer of the substrate in the areas that are not protected by photoresist. In semiconductor fabrication, dry etching techniques are generally used, as they can be made anisotropic, in order to avoid significant undercutting of the photoresist pattern. This is essential when the width of the features to be defined is similar to or less than the thickness of the material being etched (i.e., when the aspect ratio approaches unity).

Plasma etching involves a high-speed stream of glow discharge (plasma) of an appropriate gas mixture being shot (in pulses) at a sample. The plasma source, known as etch species, can be either charged (ions) or neutral (atoms and radicals). During the process, the plasma will generate volatile etch products from the chemical reactions between the elements of the material etched and the reactive species generated by the plasma. Eventually the atoms of the shot element embed themselves at or just below the surface of the target, thus modifying the physical properties of the target.

Reactive-ion etching (RIE) is a type of dry etching which has different characteristics than wet etching. RIE uses chemically reactive plasma to remove material deposited on wafers. The plasma is generated under low pressure (vacuum) by an electromagnetic field. High-energy ions from the plasma attack the wafer surface and react with it.

Deep reactive-ion etching (DRIE) is a highly anisotropic etch process used to create deep penetration, steep-sided holes and trenches in wafers/substrates, typically with high aspect ratios. It was developed for microelectromechanical systems (MEMS), which require these features, but is also used to excavate trenches for high-density capacitors for DRAM and more recently for creating through silicon via's (TSV)'s in advanced 3D wafer level packaging technology. There are two main technologies for high-rate DRIE: cryogenic and Bosch, although the Bosch process is the only recognised production technique. Both Bosch and cryo processes can fabricate 90° (truly vertical) walls, but often the walls are slightly tapered, e.g. 88° (“reentrant”) or 92° (“retrograde”). Sidewall passivation can be used where functional groups condense on the sidewalls and protect the sidewalls from lateral etching. As a combination of these processes deep vertical structures can be made.

Photoresist removal. After a photoresist is no longer needed, it must be removed from the substrate. This usually requires a liquid “resist stripper”, which chemically alters the resist so that it no longer adheres to the substrate. Alternatively, photoresist may be removed by a plasma containing oxygen, which oxidizes it. This process is called ashing, and resembles dry etching. When the resist has been dissolved, the solvent can be removed by heating to 80° C. without leaving any residue.

### Examples

The following examples as well as the figures are included to demonstrate preferred embodiments of the invention. It should be appreciated by those of skill in the art that the techniques disclosed in the examples or figures represent techniques discovered by the inventors to function well in the practice of the invention, and thus can be considered to constitute preferred modes for its practice. However, those of skill in the art should, in light of the present disclosure, appreciate that many changes can be made in the specific embodiments which are disclosed and still obtain a like or similar result without departing from the spirit and scope of the invention.

### Materials and Methods

Silicone hard-coated polycarbonate (SHC-PC) (1.2 mm thick) sheets were obtained from (SABIC EXATEC). EC3027 photoresist and AZ726 MIF developer were provided by Microchemicals GmbH. All other reagents were clean room grade solvents and used without purification. Surface characterization images were taken by using Field Emission Gun (FEG Quanta 600) Scanning Electron Microscopy (SEM) equipped EDEX accessories of 5-10 KV. The samples were sputter coated with 5 nm layer of (Au/Pd) using K575X (Au/Pd) target sputter coater using (20 mA, 40 s) prior imaging. Water contact angles were measured using contact angle goniometer (KRUSS, DSA100) at five different points of the sample using of 10 μL of deionized water, and the mean values are reported. X-ray photoelectron spectroscopy (XPS) measurements were carried out in a UHV Omicron chamber equipped with a SPHERA U7 hemispherical energy analyzer, using X-ray photons with an incident kinetic energy of 1486.6 eV from a monochromated Al K α X-ray source with a total energy resolution of 0.1 eV. A Zygo (NewView 7300) was used for large surface optical image profiling.

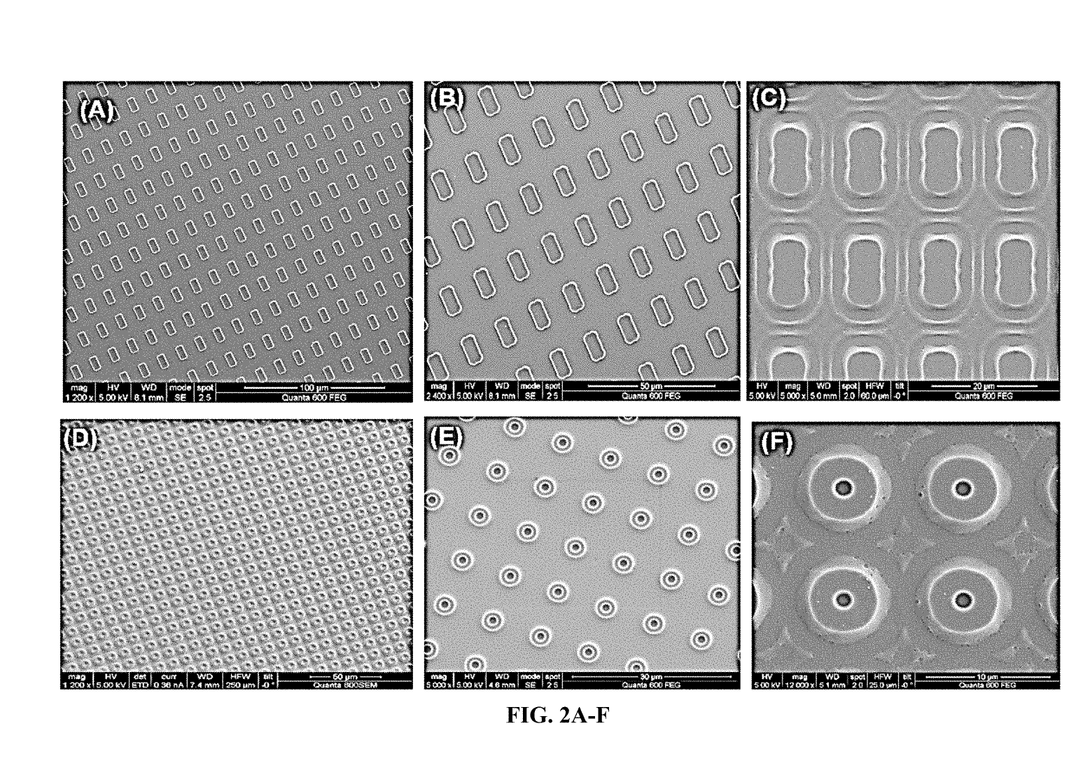

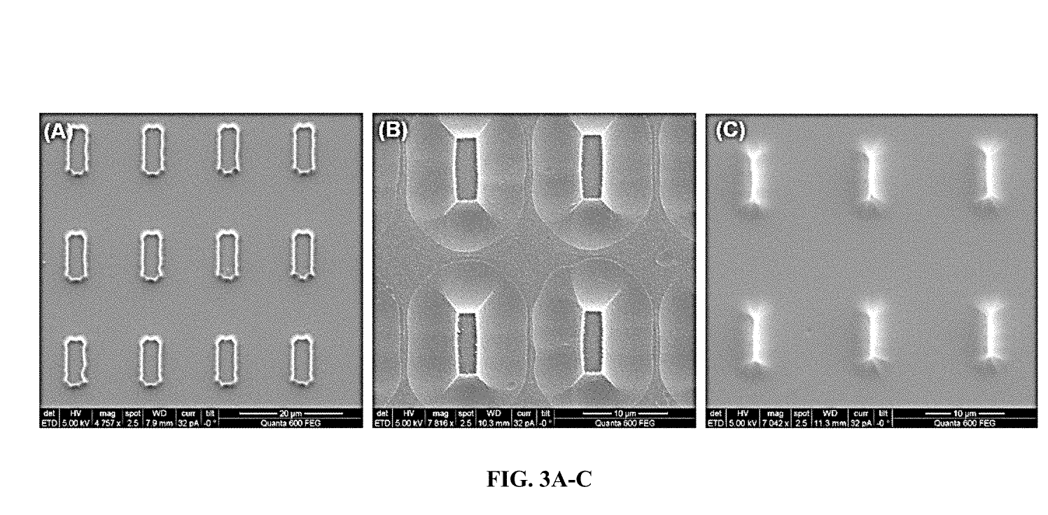

SEM images exhibiting the formation of the desired hierarchical structures after plasma etching and deposition are shown in (FIG. 2 and FIG. 3). Textured pattern of rectangular and circular shape pillars with edge gap ratios (4.49/9.65 μm versus nominal 5/10 μm) with minimal side-wall tapering of pillars due to isotropic attach of oxygen plasma were observed. An array of pillars on a large area comprising of vertically etched structures with pillars height of (3.65 μm) were evident in the SEM images. However, excessive exposure of the sheets to oxygen plasma produces side-wall tapered structures with increased hydrophobicity with water contact angle exceeding ˜140°.

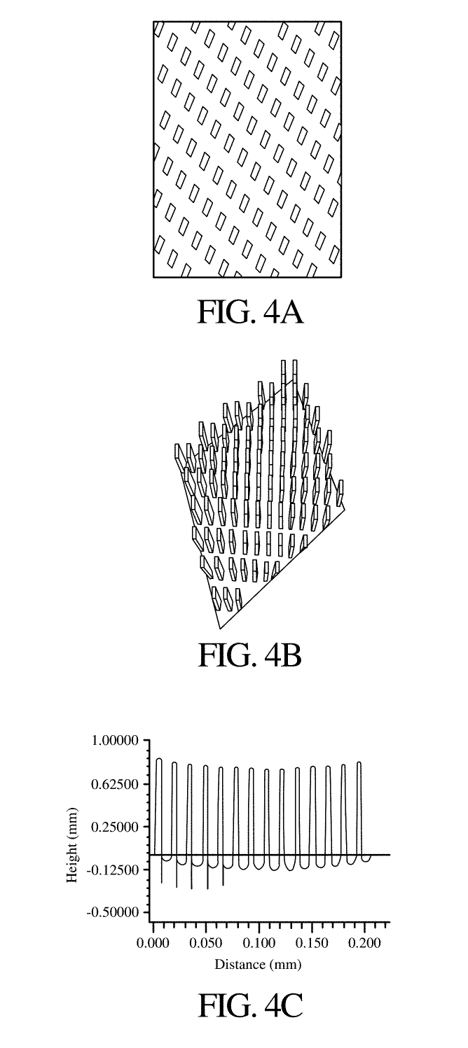

Zygo optical profiler was used to measure the surface topography of the all microfabricated surfaces. A surface height map can be seen for the micro-patterned polycarbonate with rectangular features as in (FIG. 4A). A three-dimensional map is also shown (FIG. 4B). A scan size of (5×5 cm) was used to obtain a sufficient amount of rectangular pillars to characterize the surface but also to maintain enough resolution to get an accurate measurement. The images found with the optical profiler show that the flat-topped, rectangular pillars on the (SHC-PC) surface are distributed over the entire surface in a square grid with almost the same pitch values (FIG. 4C).

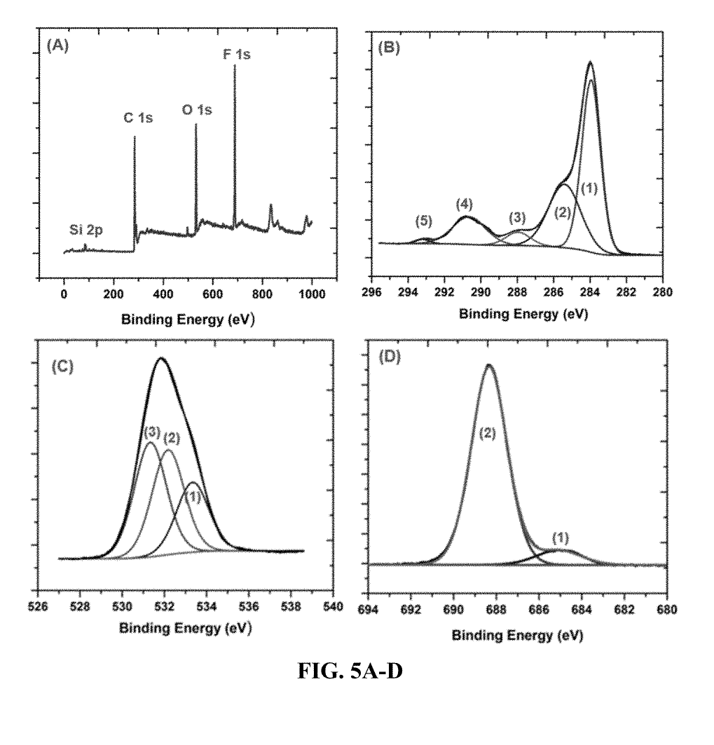

The local surface chemical composition and surface morphology are dictate the wetting properties of these micro-patterned surfaces. X-ray photoelectron spectroscopy (XPS) was employed to probe the chemical composition and the degree of surface coating of plasma deposited low surface energy material (C_{I}F′ₛ). FIG. 5A-FIG. 5D shows a representative example of survey spectrum of micro-patterned silicone hard-coated polycarbonate (SHC-PC) (rectangular patterns) surface as well as high resolution spectra of C 1s, O 1s, F 1s and Si 2p. The survey spectrum (FIG. 5A) clearly exhibits peaks at 99.7, 284.7, 531.9, 687.9 eV corresponding to the binding energies of Si 2p, C 1 s, O 1 s, and F 1 s, respectively. High resolution XPS scan was also carried out to gain additional insight into the chemical composition of the coatings. FIG. 5B-FIG. 5D shows the high resolution for carbon, oxygen, fluorine, and silicon as the major chemical components of the micro-patterned films.

High resolution scan for C 1s spectrum as shown in FIG. 5B is deconvoluted into five components with binding energies characteristic of the expected chemical constituents of the film. Specifically, —C-C/C-H (284.7 eV), —C—O/—CH₂CF₂— (286.6 eV), —C-C═O (288.5 eV), —CF₂— (291.2 eV) and —CF₃— (293.3 eV) were observed. Peak fitting were summed when significant overlap prevented unambiguous deconvolution for binding energies for specific elements, and in these case the presence of attenuated SiO₂ peaks for silicone hard-coated layer. The O 1s core level peaks are observed at 531.2 eV for (—C—O—C), 532.5 eV for SiO₂ and 533.7 eV for (—C-C═O) respectively. The XPS scan for F 1s confirms the presence of peak at 688.4 eV assigned to fluorine followed by a shoulder at 685.1 eV for fluorosilicas (Si-F) stemming from the reaction exchange of the silanol groups on the silica with fluorine. XPS data clearly confirms the surface composition of these films are rich in perfluoro-alkyl (CF and CF₃) moieties that are important in lowering their surface free energy.

The wetting behavior of the films were evaluated by measuring the static water contact angle (WCA) at three different locations of the films. Native hard-coated polycarbonate revealed water contact angles of 82°. As expected, after plasma incorporation of low surface energy perfluoro compound such as (CF₄ or C₄F₈) into the micro-patterned surfaces resulted in films with greater hydrophobicity (WCA 122°). The observed wetting properties of these films and the water contact angle values reported herein are characteristic of films containing —CF₃ groups at the interface as supported by the XPS analysis.

1. A micron patterned silicone hard-coated polymer comprising a micropatterned silicone surface having (a) three-dimensional surface features and (b) a water contact angle (WCA) of between 15° and 125°.

2. The micron patterned silicone hard-coated polymer of claim 1, wherein the three dimensional surface features have a rectangular, square, polygonal, circular, or elliptical base.

3. The micron patterned silicone hard-coated polymer of claim 2, wherein the surface features are semi-spherical, cubes, polygonal columns, cylinders, cones, triangular prisms, or pyramids.

4. The micron patterned silicone hard coated polymer of claim 3, wherein the polygonal column is a rectangular column.

5. The micron patterned silicone hard-coated polymer of claim 1, wherein the surface features are about 1 to 10 μm in height.

6. The micron patterned silicone hard-coated polymer of claim 1, wherein the surface features have an aspect ratio of about 0.5 to 3 μm.

7. The micron patterned silicone hard-coated polymer of claim 1, wherein the surface features are spaced at about 5 to 15 μm center to center from each other.

8. The micron patterned silicone hard-coated polymer of claim 1, wherein the surface has a roughness from 5 nm to 100 nm.

9. The micron patterned silicone hard-coated polymer of claim 1, further comprising a hydrophobic coating forming a coated hydrophobic silicone hard-coated polymer.

10. The micron patterned silicone hard-coated polymer of claim 9, wherein the hydrophobic coating has a thickness of 5 nm to 1 μm.

11. The micron patterned silicone hard-coated polymer of claim 9, wherein the hydrophobic coating is a fluorinated polymeric film.

12. The micron patterned silicone hard-coated polymer of claim 11, wherein the fluorinated polymeric film is a C₄F₈, CF₄, polytetrafluoroethylene (PTFE), polychlorotrifluoroethylene (PCTFE), polyvinylidenefluoride (PVDF), polyvinylfluoride (PVF), ethylene/chlorotrifluoroethylene copolymer (ECTFE), ethylene/trifluoroethylene copolymer (ETFE), fluorinated ethylene/propylene copolymer (FEP), trifluoroethylene/perfluoropropylvinylether (PFA), poly(TFE-co-HFP-co-VDF) (THV), perfluoro-3-butenyl-vinly ether (PBVE), or tetrafluoroethylene/perfluoro-2,2-dimethyl-1,3-dioxole copolymer polymeric film.

13. The micron patterned silicone hard-coated polymer of claim 11, wherein the coated hydrophobic silicone hard-coated polymer has a surface composition of about 45 to 50% O1s, 9 to 11% C1s, 1 to 3% F1s, and 30 to 45% Si2p.

14. The micron patterned silicone hard-coated polymer of claim 1, wherein the polymer is polycarbonate.

15. A flexible film comprising a micron patterned silicone hard-coated polymer comprising a micron patterned surface having (a) three-dimensional surface features, and (b) a water contact angle (WCA) of between 15° and 125° that is mechanically flexible and has a bend radius of between 0.005 to 10 mm.

16. The micron patterned silicone hard-coated polymer of claim 1, wherein the micron patterned silicone hard-coated polymer is comprised in a microfluidic or micromechanical device, wherein the micron patterned silicone hard-coated polymer has a water contact angle (WCA) greater than 90°.

17. A method for patterning a silicone hard-coat (SHC) substrate comprising the steps of:
(a) applying a photoresist (PR) coating to a silicone hard-coat (SHC) substrate surface to form a photoresist coated substrate;
(b) exposing the photoresist coated substrate to ultraviolet light in the presence of a photomask;
(c) developing the exposed photoresist coated substrate to form a patterned substrate;
(d) exposing the patterned substrate to a first plasma etching to form a first plasma etched substrate; and
(e) exposing the first plasma etched substrate to a second plasma etching comprising reactive ion-etching (ME) to form a micron patterned substrate.

18. The method of claim 17, further comprising applying a metal mask to portions of the substrate prior to applying the photoresist coating.

19. The method of claim 17, wherein applying the photoresist is by spin-coating the substrate with the photoresist.

20. The method of claim 17, wherein the photoresist layer is between 1 and 10 μm thick.
